(19) United States
(12) Patent Application Publication
(10) Pub. No.: US 2025/0327860 A1
(43) Pub. Date: Oct. 23, 2025

(54) DEBUG INFRASTRUCTURE FOR MEMORY SYSTEMS

(71) Applicant: Micron Technology, Inc., Boise, ID (US)

(72) Inventors: Nitul Gohain, Bangalore (IN); John Maroney, Irvine, CA (US)

(21) Appl. No.: 19/174,435

(22) Filed: Apr. 9, 2025

Related U.S. Application Data
(60) Provisional application No. 63/635,721, filed on Apr. 18, 2024.

(51) Int. Cl. G01R 31/317; G01R 31/3185

(52) U.S. Cl. CPC G01R 31/31705; G01R 31/31722; G01R 31/318588

(57) ABSTRACT

Aspects of the present disclosure configure a system component, such as a memory sub-system controller, to debug a memory sub-system. The controller receives, from a host over a first bus, authentication information associated with unlocking the debugging component and, in response to successfully authenticating the host based on the authentication information, unlocks a debugging component. The debugging component receives one or more debug commands from the host via a second bus and transmits, to the host via the second bus, debugging information in response to receiving the one or more debug commands.

### PRIORITY APPLICATION

This application claims the benefit of priority to U.S. Provisional Application Ser. No. 63/635,721, filed Apr. 18, 2024, which is incorporated herein by reference in its entirety.

### TECHNICAL FIELD

Examples of the disclosure relate generally to memory sub-systems and, more specifically, to debugging a memory sub-system.

### BACKGROUND

A memory sub-system can be a storage system, such as a solid-state drive (SSD), and can include one or more memory components that store data. The memory components can be, for example, non-volatile memory components and volatile memory components. In general, a host system can utilize a memory sub-system to store data at the memory components and to retrieve data from the memory components.

### BRIEF DESCRIPTION OF THE DRAWINGS

The present disclosure will be understood more fully from the detailed description given below and from the accompanying drawings of various examples of the disclosure.

FIG. 1 is a block diagram illustrating an example computing environment including a memory sub-system with a debugging component, in accordance with some examples.

FIG. 2 is a block diagram of an example debugging component, in accordance with some examples.

FIG. 3 is a flow diagram of an example method to perform memory sub-system debugging operations, in accordance with some examples.

FIG. 4 is an example data packet format to perform memory sub-system debugging operations, in accordance with some examples.

FIG. 5 is an example flow diagram of communicating with the debugging component, in accordance with some examples.

FIG. 6 is a block diagram illustrating a diagrammatic representation of a machine in the form of a computer system within which a set of instructions can be executed for causing the machine to perform any one or more of the methodologies discussed herein, in accordance with some examples.

### DETAILED DESCRIPTION

Aspects of the present disclosure configure a system component, such as a memory sub-system controller, to unlock a debugging component (e.g., a universal asynchronous receiver-transmitter (UART) device) for enabling a host to debug or initiate debugging operations for a memory sub-system. By default, the debugging component may be placed in a locked state to prevent the debugging component from wasting power and/or communicating over one or more buses with a host. Once a critical event is encountered, an external source (e.g., the host or some other physical debugging device) can transmit an instruction to the memory sub-system controller to unlock the debugging component. The instruction can include authentication information. If the authentication information is verified, the external source is authenticated and the debugging component is unlocked or placed in the unlocked state. At that point, the debugging component can communicate with the external source to receive debugging commands and/or transmit debugging information to the external source. In this way, in case of failure, the memory sub-system can be debugged without having to physically disconnected or detach the memory sub-system from the host and in a way that consumes a minimal amount of additional hardware and/or processing resources.

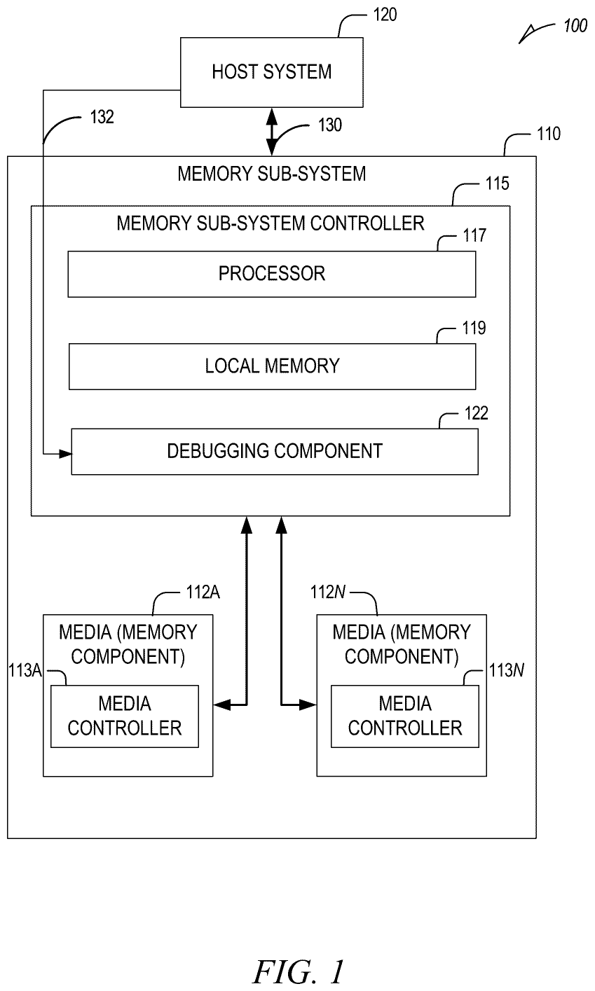

A memory sub-system can be a storage device, a memory module, or a hybrid of a storage device and memory module. Examples of storage devices and memory modules are described below in conjunction with FIG. 1. In general, a host system can utilize a memory sub-system that includes one or more memory components, such as memory devices that store data. The host system can send access requests (e.g., write command, read command, sequential write command, sequential read command) to the memory sub-system, such as to store data at the memory sub-system and to read data from the memory sub-system. The data specified by the host is hereinafter referred to as “host data” or “user data”.

A host request can include logical address information (e.g., logical block address (LBA), namespace) for the host data, which is the location the host system associates with the host data and a particular zone in which to store or access the host data. The logical address information (e.g., LBA, namespace) can be part of metadata for the host data. Metadata can also include error handling data (e.g., ECC codeword, parity code), data version (e.g., used to distinguish age of data written), valid bitmap (which LBAs or logical transfer units contain valid data), etc.

The memory sub-system can initiate media management operations, such as a write operation, on host data that is stored on a memory device. For example, firmware of the memory sub-system may re-write previously written host data from a location on a memory device to a new location as part of garbage collection management operations. The data that is re-written, for example as initiated by the firmware, is hereinafter referred to as “garbage collection data”.

“User data” can include host data and garbage collection data. “System data” hereinafter refers to data that is created and/or maintained by the memory sub-system for performing operations in response to host requests and for media management. Examples of system data include, and are not limited to, system tables (e.g., logical-to-physical address mapping table), data from logging, scratch pad data, etc.

A memory device can be a non-volatile memory device. A non-volatile memory device is a package of one or more dice. Each die can comprise one or more planes. For some types of non-volatile memory devices (e.g., NAND devices), each plane comprises a set of physical blocks. For some memory devices, blocks are the smallest area than can be erased. Each block comprises a set of pages. Each page comprises a set of memory cells, which store bits of data. The memory devices can be raw memory devices (e.g., NAND), which are managed externally, for example, by an external controller. The memory devices can be managed memory devices (e.g., managed NAND), which is a raw memory device combined with a local embedded controller for memory management within the same memory device package. The memory device can be divided into one or more zones where each zone is associated with a different set of host data or user data or application.

Debugging a solid state drive (SSD) when it fails in an automotive environment presents a unique set of challenges that stem from the complex interplay between advanced electronics and the demanding conditions inherent to automotive applications. One of the primary difficulties is the harsh operating environment, which includes extreme temperature fluctuations, vibrations, and shocks that are not typically encountered in standard computing environments. These factors can lead to intermittent hardware failures that are difficult to replicate and diagnose in a controlled setting. Automotive SSDs are also integrated within a network of interconnected systems that rely on real-time data exchange, such as navigation, infotainment, and driver-assistance systems (ADAS). A failure in the SSD can have cascading effects, making it challenging to isolate the root cause. The drive's operation is influenced by the vehicle's power fluctuations, electromagnetic interference, and the need for continuous operation over extended periods, which can lead to wear and tear not commonly seen in other SSD applications. This wear can manifest in subtle ways, affecting the drive's firmware and leading to complex failure modes that require specialized diagnostic tools and expertise to decode error logs and understand the failure mechanisms. Debugging these drives requires not only a restoration of function but also a recovery of data, which can be particularly challenging if the drive's failure has compromised the file system integrity. Automotive SSDs must adhere to stringent safety and reliability standards, and debugging often needs to be conducted within the framework of these regulations, adding another layer of complexity to the process.

Adding to the already complex challenges of debugging an SSD in an automotive environment, the failure of the Peripheral Component Interconnect Express (PCIe) interface significantly compounds the difficulty, especially when other means of communicating with the drive are not readily available. PCIe serves as the primary high-speed interface that connects the SSD to the vehicle's computing systems, and its failure can disrupt the entire data flow, making it challenging to determine whether issues are arising from the SSD itself or from the communication channel. When PCIe fails, one of the immediate challenges is the loss of a reliable pathway to retrieve diagnostic data from the SSD. This impedes the ability to perform read/write operations and to access the drive's SMART (Self-Monitoring, Analysis, and Reporting Technology) attributes, which are crucial for assessing the health and status of the drive. Without access to this data, pinpointing the cause of the failure requires alternative indirect methods, which may not be as precise or informative. Furthermore, PCIe failure can lead to a complete inability to recognize the SSD within the system, akin to the drive being physically absent. This presents a significant hurdle in debugging, as standard tools and software used for drive analysis may be unable to detect the SSD, let alone interact with it. Technicians may need to resort to using specialized equipment or physically removing the SSD from the automotive environment altogether for testing, which is not always feasible or representative of the in-situ conditions that may have contributed to the failure. This can also lead to wasted resources, time and effort if the failure could have been identified through other means.

The disclosed examples address these challenges by adding a physical debugging component that is in a disabled or locked state by default and is only enabled when needed to debug the memory sub-system, such as in case of failure. The memory sub-system may be embodied or implemented in an automotive environment, making it challenging to debug without physically removing the memory sub-system. By enabling the debugging component to receive, from the host, debug commands securely and perform debug operations out-of-band, such as by using a different communication bus (than the default communication bus used to communicate with the host), the automotive memory sub-system can be debugged without having to be physically removed.

Specifically, the disclosed techniques receive, from a host over a first bus, authentication information associated with unlocking the debugging component. The disclosed techniques, in response to successfully authenticating the host based on the authentication information, unlock the debugging component. The debugging component can receive one or more debug commands from the host via a second bus and transmit, to the host via the second bus, debugging information in response to receiving the one or more debug commands. The debugging information can include a state of the memory sub-system representing a status of at least one of one or more data structures, one or more queues, or one or more state machines.

The debugging component can receive additional authentication information from the host via the second bus. The debugging component processes the one or more debug commands in response to successfully authenticating the host based on the additional authentication information. In some cases, the additional authentication information includes a single use password (SUP). The first bus can include a system management bus (SMBus) and the second bus can include a peripheral component interconnect express (PCIe) bus.

The debugging component includes a universal asynchronous receiver-transmitter (UART) device. In some examples, the authentication information includes a 256-bit key, and the processing device successfully authenticates the host by comparing the authentication information with a known value.

The one or more debug commands can include instructions to install debug firmware. In such cases, the debugging component causes the processing device to boot using the debug firmware instead of default firmware. The debug firmware can be configured to generate different types of debugging information than the default firmware. In some cases, the memory sub-system is installed in an automotive environment and is associated with at least one of an infotainment system of the automotive environment or advanced driver assistance systems (ADAS) of the automotive environment. In such cases, the one or more debug commands can be provided to the debugging component without physically detaching the memory sub-system from the host.

The debugging information can include at least one of at least one of NVMe logs, FailureAnalysisDump/VendorSpecific logs, SMART logs, or SMART extended logs. The one or more debug commands can include at least one of a sanitize command to delete information stored in a set of memory components of the memory sub-system, a request to place the memory sub-system in a specific power state that prevents the memory sub-system from entering a low-power mode, a request to modify speed of the memory sub-system or clocking mode of the memory sub-system, or a request to restructure a namespace of the memory sub-system.

In some cases, the authentication information can be received in response to occurrence of a critical event of the memory sub-system. The critical event can include at least one of PCIe link drops, firmware asserts, command timeouts, entering of a write protect state in the memory sub-system, a loop of resets, a threshold number of interrupts being transmitted by the processing device to the host.

In some examples, the debugging component periodically sends a waiting-for-packet indicator. The debugging component receives one or more start-of-packet indicators from the host associated with respective one or more packets. The debugging component sends an acknowledgment after receiving each of the one or more packets and receives an end-of-transmission (EOT) indicator after the one or more packets are received. The debugging component receives an end-of-transmission block (ETB) indicator to switch the debugging component from operating as a receiver to operating as a transmitter. The one or more debug commands are received as part of the one or more packets, and the debugging information can be transmitted after the debugging component switches to operating as the transmitter.

In some cases, the debugging component detects an additional waiting-for-packet indicator received from the host. The debugging component, in response to detecting the additional waiting-for-packet indicator, transmits a start-of-packet indicator associated with a debugging packet to the host and sends the EOT indicator after the debugging packet is transmitted. The debugging component transmits the ETB indicator to switch the host from operating as the receiver to operating as the transmitter. In some examples, the debugging component returns to the locked state in response to receiving a lock command in the one or more debug commands.

Though various examples are described herein as being implemented with respect to a memory sub-system (e.g., a controller of the memory sub-system), some or all of the portions of an example can be implemented with respect to a host system, such as a software application or an operating system of the host system.

FIG. 1 illustrates an example computing environment 100 including a memory sub-system 110, in accordance with some examples. The memory sub-system 110 can include media, such as memory components 112A to 112N (also hereinafter referred to as “memory devices”). The memory components 112A to 112N can be volatile memory devices, non-volatile memory devices, or a combination of such. In some examples, the memory sub-system 110 is a storage system. A memory sub-system 110 can be a storage device, a memory module, or a hybrid of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, and a hard disk drive (HDD). Examples of memory modules include a dual in-line memory module (DIMM), a small outline DIMM (SO-DIMM), and a non-volatile dual in-line memory module (NVDIMM).

The computing environment 100 can include a host system 120 that is coupled to a memory system via one or more primary buses 130 (e.g., an SMBus, a PCIe bus, or other suitable communication bus). The memory system can include one or more memory sub-systems 110. In some examples, the host system 120 is coupled to different types of memory sub-system 110. FIG. 1 illustrates one example of a host system 120 coupled to one memory sub-system 110. The host system 120 uses the memory sub-system 110, for example, to write data to the memory sub-system 110 and read data from the memory sub-system 110. As used herein, “coupled to” generally refers to a connection between components, which can be an indirect communicative connection or direct communicative connection (e.g., without intervening components), whether wired or wireless, including connections such as electrical, optical, magnetic, etc.

The host system 120 can be a computing device such as a desktop computer, laptop computer, network server, mobile device, embedded computer (e.g., one included in a vehicle, industrial equipment, or a networked commercial device), or such computing device that includes a memory and a processing device. The host system 120 can include an automotive environment associated with one or more automotive systems, such as an ADAS and/or infotainment system. The host system 120 can include or be coupled to the memory sub-system 110 so that the host system 120 can read data from or write data to the memory sub-system 110.

The host system 120 can be coupled to the memory sub-system 110 via a physical host interface, such as one or more primary buses 130. Examples of a physical host interface include, but are not limited to, a serial advanced technology attachment (SATA) interface, a peripheral component interconnect express (PCIe) interface, a universal serial bus (USB) interface, a Fibre Channel interface, a Serial Attached SCSI (SAS) interface, SMBus interface, etc. The physical host interface can be used to transmit data between the host system 120 and the memory sub-system 110. The host system 120 can further utilize an NVM Express (NVMe) interface to access the memory components 112A to 112N when the memory sub-system 110 is coupled with the host system 120 by the PCIe interface. The physical host interface can provide an interface for passing control, address, data, and other signals (e.g., download and commit firmware commands/requests) between the memory sub-system 110 and the host system 120.

The memory components 112A to 112N can include any combination of the different types of non-volatile memory components and/or volatile memory components. An example of non-volatile memory components includes a negative-and (NAND)-type flash memory. Each of the memory components 112A to 112N can include one or more arrays of memory cells such as single-level cells (SLCs) or multi-level cells (MLCs) (e.g., TLCs or QLCs). In some examples, a particular memory component 112 can include both an SLC portion and an MLC portion of memory cells. Each of the memory cells can store one or more bits of data (e.g., blocks) used by the host system 120. Although non-volatile memory components such as NAND-type flash memory are described, the memory components 112A to 112N can be based on any other type of memory, such as a volatile memory.

In some examples, the memory components 112A to 112N can be, but are not limited to, random access memory (RAM), read-only memory (ROM), dynamic random access memory (DRAM), synchronous dynamic random access memory (SDRAM), phase change memory (PCM), magnetoresistive random access memory (MRAM), negative-or (NOR) flash memory, electrically erasable programmable read-only memory (EEPROM), and a cross-point array of non-volatile memory cells. A cross-point array of non-volatile memory cells can perform bit storage based on a change of bulk resistance, in conjunction with a stackable cross-gridded data access array. Additionally, in contrast to many flash-based memories, cross-point non-volatile memory can perform a write-in-place operation, where a non-volatile memory cell can be programmed without the non-volatile memory cell being previously erased. Furthermore, the memory cells of the memory components 112A to 112N can be grouped as memory pages or blocks that can refer to a unit of the memory component 112 used to store data. In some examples, the memory cells of the memory components 112A to 112N can be grouped into a set of different zones of equal or unequal size used to store data for corresponding applications. In such cases, each application can store data in an associated zone of the set of different zones.

The memory sub-system controller 115 can communicate with the memory components 112A to 112N to perform operations such as reading data, writing data, or erasing data at the memory components 112A to 112N and other such operations. The memory sub-system controller 115 can include hardware such as one or more integrated circuits and/or discrete components, a buffer memory, or a combination thereof. The memory sub-system controller 115 can be a microcontroller, special-purpose logic circuitry (e.g., a field programmable gate array (FPGA), an application specific integrated circuit (ASIC), etc.), or another suitable processor. The memory sub-system controller 115 can include a processor (processing device) 117 configured to execute instructions stored in local memory 119. In the illustrated example, the local memory 119 of the memory sub-system controller 115 includes an embedded memory configured to store instructions for performing various processes, operations, logic flows, and routines that control operation of the memory sub-system 110, including handling communications between the memory sub-system 110 and the host system 120. In some examples, the local memory 119 can include memory registers storing memory pointers, fetched data, and so forth. The local memory 119 can also include read-only memory (ROM) for storing microcode. While the example memory sub-system 110 in FIG. 1 has been illustrated as including the memory sub-system controller 115, in another example of the present disclosure, a memory sub-system 110 may not include a memory sub-system controller 115, and can instead rely upon external control (e.g., provided by an external host, or by a processor 117 or controller separate from the memory sub-system 110).

In general, the memory sub-system controller 115 can receive I/O commands or operations from the host system 120 and can convert the commands or operations into instructions or appropriate commands to achieve the desired access to the memory components 112A to 112N. The memory sub-system controller 115 can be responsible for other operations, based on instructions stored in firmware in an active slot or associated with an active firmware slot, such as wear leveling operations, garbage collection operations, error detection and ECC operations, decoding operations, encryption operations, caching operations, address translations between a logical block address and a physical block address that are associated with the memory components 112A to 112N, address translations between an application identifier received from the host system 120 and a corresponding zone of a set of zones of the memory components 112A to 112N. This can be used to restrict applications to reading and writing data only to/from a corresponding zone of the set of zones that is associated with the respective applications. In such cases, even though there may be free space elsewhere on the memory components 112A to 112N, a given application can only read/write data to/from the associated zone, such as by erasing data stored in the zone and writing new data to the zone. The memory sub-system controller 115 can further include host interface circuitry to communicate with the host system 120 via the physical host interface. The host interface circuitry can convert the I/O commands received from the host system 120 into command instructions to access the memory components 112A to 112N as well as convert responses associated with the memory components 112A to 112N into information for the host system 120.

The memory sub-system 110 can also include additional circuitry or components that are not illustrated. In some examples, the memory sub-system 110 can include a cache or buffer (e.g., DRAM or other temporary storage location or device) and address circuitry (e.g., a row decoder and a column decoder) that can receive an address from the memory sub-system controller 115 and decode the address to access the memory components 112A to 112N.

The memory devices can be raw memory devices (e.g., NAND), which are managed externally, for example, by an external controller (e.g., memory sub-system controller 115). The memory devices can be managed memory devices (e.g., managed NAND), which is a raw memory device combined with a local embedded controller (e.g., local media controllers) for memory management within the same memory device package. Any one of the memory components 112A to 112N can include a media controller (e.g., media controller 113A and media controller 113N) to manage the memory cells of the memory component, to communicate with the memory sub-system controller 115, and to execute memory requests (e.g., read or write) received from the memory sub-system controller 115.

In some examples, the memory sub-system controller 115 can include a debugging component 122 (which can be a bidirectional communication device that supports the NVMe-MI over UART protocol over XMODEM). The debugging component 122 can be placed by default in an inactive or locked state. In this state, the debugging component 122 does not perform certain debugging operations and does not transmit any information on the one or more primary buses 130 or any other bus. A debug port associated with the debugging component 122 can be disabled when the debugging component 122 is in the locked state. In some cases, the one or more primary buses 130 can fail to operate properly, such as when a critical failure occurs in the memory sub-system 110. In such cases, the host system 120 can communicate with the memory sub-system controller 115 via a side-band channel 132. The side-band channel can include an SMBus or other bus that differs from the one or more primary buses 130.

In such cases, the host system 120 can transmit an instruction to the memory sub-system controller 115, along with authentication information (e.g., a 256-bit encryption key), to unlock the debugging component 122 and place the debugging component 122 in the active state. The memory sub-system controller 115 can verify that the authentication information is valid, such as by comparing an encryption key received from the host system 120 with a known value. In response to the memory sub-system controller 115 successfully authenticating the host system 120, the memory sub-system controller 115 enables the debugging component 122 and unlocks the debug port associated with the debugging component 122. At this point, the debugging component 122 is transitioned to the unlocked state and begins communicating with the host system 120 via the side-band channel 132 and/or the one or more primary buses 130. The debugging component 122 can receive debug commands from the host system 120 and can perform debug operations based on the debug commands received from the host system 120. The debugging component 122 can transmit debug information to the host system 120 over the one or more primary buses 130 and/or the side-band channel 132 based on the debug commands. This enables the host system 120 or some other external source to debug failure of the memory sub-system 110 without having to physically remove or detach the memory sub-system 110 from a ball grid array or other physical connection to a printed circuit board (PCB).

Depending on the example, the debugging component 122 can comprise logic (e.g., a set of transitory or non-transitory machine instructions, such as firmware) or one or more components that causes the memory sub-system 110 (e.g., the memory sub-system controller 115) to perform operations described herein with respect to the debugging component 122. The debugging component 122 can comprise a tangible or non-tangible unit (and/or instructions) capable of performing operations described herein.

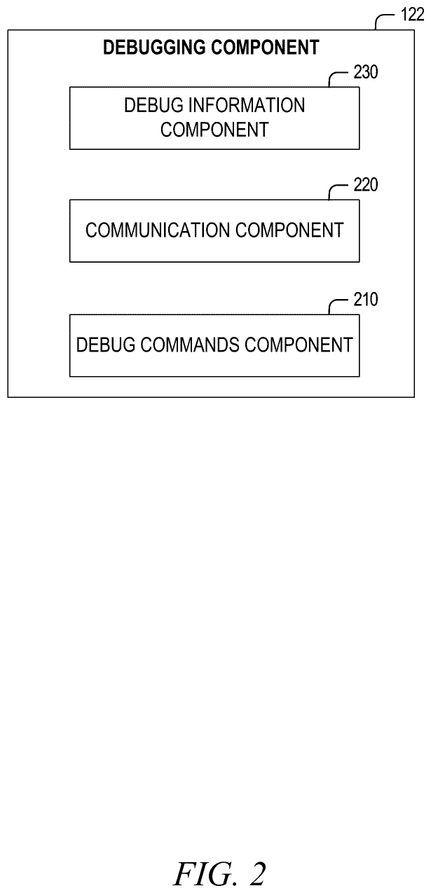

FIG. 2 is a block diagram of an example debugging component 122, in accordance with some examples. As illustrated, the debugging component 122 includes a debug information component 230, a communication component 220, and a debug commands component 210. The debug information component 230 stores a list of error events that are monitored and encountered by the memory sub-system 110. For example, the debug information component 230 can be programmed or configured to monitor the state of certain registers, FIFO buffers, command queues, and other memory sub-system 110 components and modules. Based on a combination of states of the components and modules being monitored, the debug information component 230 can be configured to generate different critical event trigger data (e.g., different error codes) and provide such error codes when requested by the host system 120 via one or more debug commands. The critical event trigger data can include at least one of Non-Volatile Memory Express (NVMe) command timeout being triggered, Cyclic Redundancy Code (CRC) Errors exceeding a CRC threshold, PCIe AXI Error event, Uncorrectable Errors (UE) event, read or write completion latency exceeding a read or write threshold, reset event information, PCIe link drops, firmware asserts, command timeouts, entering of a write-protect state in the memory sub-system, a loop of resets, a threshold number of interrupts being transmitted by the processing device to the host, and/or memory parity errors exceeding a parity threshold.

In some examples, the debug information component 230 can store instances of the full snapshots (captured at different points in time) in a first reserved portion of the set of memory components 112A to 112N. The debug information component 230 can store instances of the partial snapshots (captured at different points in time) in a second reserved portion of the set of memory components 112A to 112N. This way, partial snapshots (collected in the process of performing the second error handling mode) can be accessed and represent a state of the memory sub-system 110 separately from the full snapshots (collected in the process of performing the first error handling mode). In some examples, the debug information component 230 can selectively displace or replace a previously stored instance of debug information (full snapshot and/or partial snapshot) when a new instance of debug information is received.

As another example, the debug information component 230 can compute a second condition by accessing a power ON time for the memory sub-system 110 indicating how long the memory sub-system 110 has been powered ON since the one or more previously stored partial snapshots have been stored. The debug information component 230 can also compute an average quantity of I/O command completion rates representing the number of I/O commands that have been completed within a given period of time. If the power ON time transgresses or corresponds to a threshold period of time or range (e.g., between 60 seconds and 900 seconds) and if the average quantity of I/O command completion rate transgresses a threshold rate (e.g., 5 k I/O commands per second), the debug information component 230 can determine that the second condition is met and replace the one or more partial snapshots with the new partial snapshot.

In some examples, the communication component 220 can store and/or generate a single use password (SUP). The communication component 220 can receive an instruction from the memory sub-system controller 115 to switch the debugging component 122 from being in the locked state to being in the unlocked state. In response, the communication component 220 can begin waiting to receive packets from the host system 120. Specifically, the communication component 220 can transmit a waiting indicator (e.g., a ‘C’ signal having a certain value) periodically (e.g., every 3 seconds) over the side-band channel 132 and/or the one or more primary buses 130. The host system 120 can detect the waiting indicator signal from the communication component 220 and, in response to detecting the waiting indicator signal, the host system 120 can transmit a sequence of packets to the communication component 220 via the one or more primary buses 130 and/or the side-band channel 132 (or other dedicated debug physical communication port associated with the debugging component 122).

The communication component 220 can detect the sequence of packets and retrieve additional authentication information from the sequence of packets received from the host system 120. The additional authentication information can include the SUP or other certificate or encryption key. The communication component 220 can verify whether the SUP or other certificate or encryption key is valid. If so, the communication component 220 determines that the host system 120 is successfully authenticated. Namely, the host system 120 may need to be authenticated twice in order to control the debugging component 122. The host system 120 can be authenticated a first time by the memory sub-system controller 115 in order to unlock the debugging component 122. Then, the host system 120 can be authenticated a second time by the debugging component 122 in order to enable the host system 120 to send debug commands for execution by the debugging component 122. After authenticating the host, the debugging component 122 and/or the memory sub-system controller 115 can provide to the host system 120 a list of capabilities and processing commands that the debugging component 122 can perform.

After the debugging component 122 successfully authenticates the host system 120, the debugging component 122 retrieves one or more debug commands from the sequence of packets. The debug commands component 210 can process the one or more debug commands and perform debug operations according to the one or more debug commands. For example, the debug commands component 210 can assemble a sequence of debug packets that include debug information stored by the debug information component 230 in response to receiving the one or more debug packets. The debugging component 122 can receive a signal from the host system 120 indicating that a transmission session has concluded and requesting that the debugging component 122 transition to being a sender. Once the debugging component 122 confirms that the debugging component 122 has transitioned to being a sender (e.g., by sending an acknowledgement message to the host system 120), the host system 120 transitions to being a receiver.

At this point, the host system 120 begins periodically sending the waiting indicator to the debugging component 122. The debugging component 122 sends the sequence of debug packets to the host system 120 (in a similar manner as the host system 120 sent the packets to the debugging component 122). The host system 120 processes the debug packets and generates additional debug commands to send to the debugging component 122. The additional debug commands can be sent in packets after the debugging component 122 switches back to being the receiver and the host system 120 switches to being the transmitter. The additional debug commands can include a command to transition the debugging component 122 back to the locked state and to instruct the memory sub-system controller 115 to resume normal operations.

The one or more debug commands received from the host system 120 can include instructions to install debug firmware. In such cases, the debugging component 122 retrieves the debug firmware from the one or more packets received from the host system 120. The debugging component 122 stores the debug firmware in a particular firmware slot. Then, the debugging component 122 instructs the memory sub-system controller 115 to boot from the particular firmware slot instead of the default firmware slot. This results in the memory sub-system controller 115 operating using the debug firmware, which can be configured to generate different types of debugging information than the default firmware. The debugging information can include at least one of NVMe logs, FailureAnalysisDump/VendorSpecific logs, SMART logs, or SMART extended logs.

In some cases, the one or more debug commands can include at least one of a sanitize command to delete information stored in a set of memory components of the memory sub-system 110, a request to place the memory sub-system 110 in a specific power state that prevents the memory sub-system 110 from entering a low-power mode, a request to modify speed of the memory sub-system or clocking mode of the memory sub-system 110, and/or a request to restructure a namespace of the memory sub-system 110.

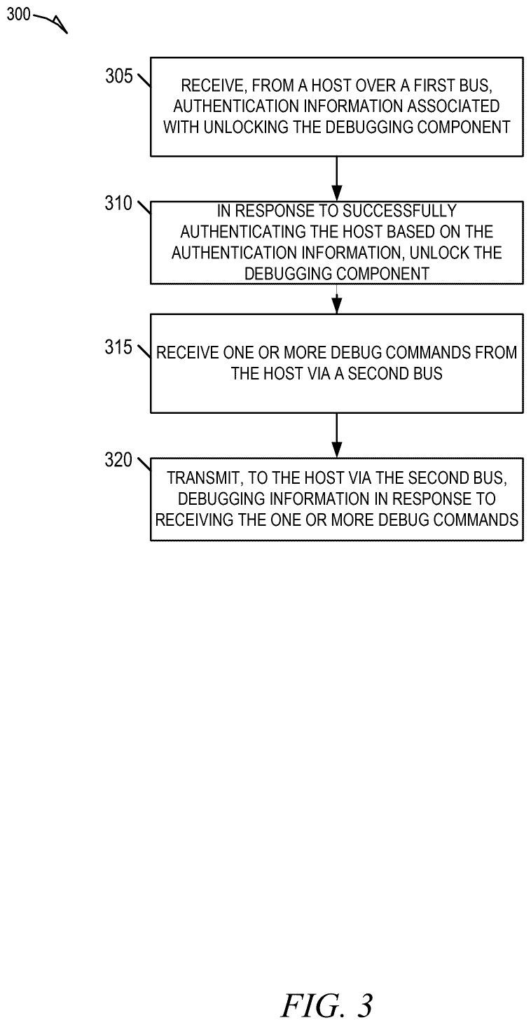

FIG. 3 is a flow diagram of an example method 300 to perform debug operations, in accordance with some examples. Method 300 can be performed by processing logic that can include hardware (e.g., a processing device, circuitry, dedicated logic, programmable logic, microcode, hardware of a device, an integrated circuit, etc.), software (e.g., instructions run or executed on a processing device), or a combination thereof. In some examples, the method 300 is performed by the memory sub-system controller 115 or subcomponents of the controller 115 of FIG. 1. In these examples, the method 300 can be performed, at least in part, by the debugging component 122. Although the processes are shown in a particular sequence or order, unless otherwise specified, the order of the processes can be modified. Thus, the illustrated examples should be understood only as examples; the illustrated processes can be performed in a different order, and some processes can be performed in parallel. Additionally, one or more processes can be omitted in various examples. Thus, not all processes are required in every example. Other process flows are possible.

Referring now to FIG. 3, the method (or process) 300 begin at operation 305, with a debugging component 122 of a memory sub-system and/or memory sub-system controller 115 receiving, from a host over a first bus, authentication information associated with unlocking the debugging component. Then, at operation 310, the memory sub-system controller 115, in response to successfully authenticating the host based on the authentication information, unlocks a debugging component by the processing device. The debugging component 122, at operation 315, receives one or more debug commands from the host via a second bus and, at operation 320, transmits, to the host via the second bus, debugging information in response to receiving the one or more debug commands.

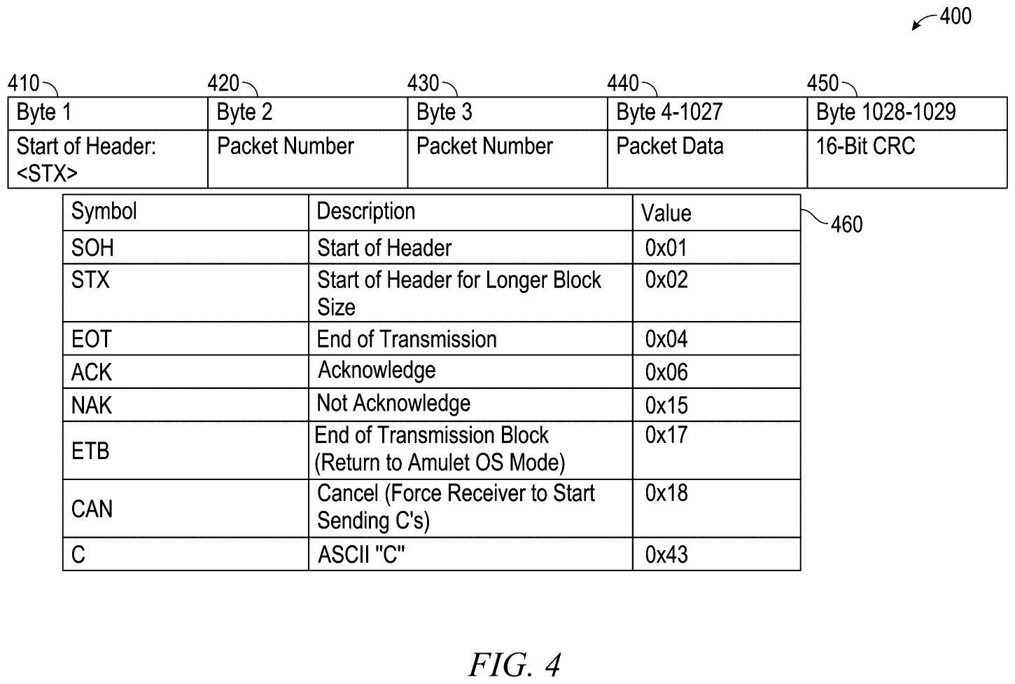

FIG. 4 is an example data packet format 400 to perform memory sub-system debugging operations, in accordance with some examples. The data packet format 400 can be used by the debugging component 122 and the host system 120 to exchange information packets during the debugging operations. In some cases, each packet can be 1 KB in size, but any other suitable size can be applied. Each packet can be formatted such that a first portion 410 includes a start-of-header indicator, a second portion 420 includes a packet number, a third portion 430 includes a packet number, a fourth portion 440 includes packet data, and a fifth portion 450 includes error correction information (e.g., cyclic redundancy correction information). The fourth portion 440 can be used to contain one or more debug commands (e.g., when the packet is being sent by the host system 120) and can be used to contain debug information (e.g., when the packet is being sent by the debugging component 122).

In some examples, the content and values that are transmitted in any one of the portions of the packet can be generated according to the table 460. For example, a start-of-header (SOH) symbol can be used to represent the start of header and stored in the first portion 410. An end of transmission (EOT) can be used to indicate that conclusion of transmission of a sequence of packets. The end-of-transmission block (ETB) can be used to indicate that a sender has no further sequences of packets to transmit and to request to switch roles with the receiver (e.g., where the receiver is instructed to become the sender and the sender switches to becoming the receiver). The C symbol can be used to periodically inform the sender that the recipient is waiting and ready to receive a sequence of packets. The ACK symbol can be used to indicate that a packet was successfully received, and the NAK symbol can be used to indicate that an error was encountered in a received packet.

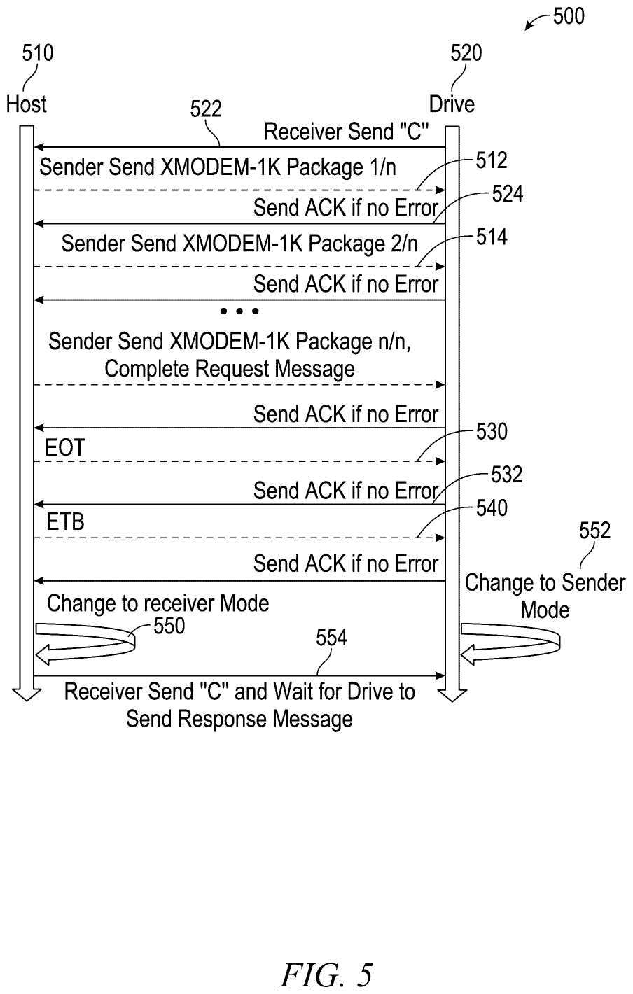

FIG. 5 is an example flow diagram of for communicating with the debugging component, in accordance with some examples. For example, after the debugging component 122 is placed in the unlocked state, the debugging component 122 (e.g., the drive 520) transmits the C symbol in a packet 522 periodically (e.g., every three seconds). This indicates to the host 510 (e.g., the host system 120) that the drive 520 is in the receiver mode and is ready to receive one or more packets. The host 510 can then generate a sequence of packets (e.g., including authentication information and/or debug commands) and send a first packet 512 in the sequence to the debugging component 122. The debugging component 122 can verify that the packet was received with no errors and sends an ACK packet 524 back to the host 510. The host 510 can then send a second packet 514 in the sequence to the debugging component 122. If an error is found, the debugging component 122 transmits a NAK symbol packet, which causes the host 510 to retransmit the last packet that was sent that had the errors. After sending the entire sequence of packets, the host 510 transmits an EOT packet 530 to the debugging component 122 indicating that the sequence of packets has concluded. The debugging component 122 sends an ACK packet 532 after receiving the EOT packet 530. At that point, the debugging component 122 processes the packets and retrieves authentication information and/or debug commands from the packets.

If the host 510 does not have any more packets to send to the debugging component 122, the host 510 transmits an ETB packet 540. The ETB packet 540 can instruct the debugging component 122 to switch from the receiver mode to the sender mode. In response to successfully receiving the ETB packet 540, the debugging component 122 transmits an ACK packet and switches to the sender mode 552. In response to receiving the ACK packet from the debugging component 122, the host 510 switches to the receiver mode 550 from being in the sender mode. Then, the host 510 begins periodically sending the C symbol packet 554 indicating to the drive 520 (e.g., the debugging component 122) that the host 510 is ready to receive packets from the debugging component 122.

The debugging component 122 can then generate a sequence of packets (e.g., including debug information) and send the sequence of packets to the host 510. The host 510 can verify that the packet was received with no errors and sends an ACK packet back to the debugging component 122. After sending the entire sequence of packets, the debugging component 122 transmits an EOT packet to the host 510 indicating that the sequence of packets has concluded. The host 510 sends an ACK packet after receiving the EOT packet and, at that point, the host 510 processes the packets and retrieves the debug information from the packets.

If the debugging component 122 does not have any more packets to send to the host 510, the debugging component 122 transmits an ETB packet. The ETB packet can instruct the host 510 to switch from the receiver mode to the sender mode. In response to successfully receiving the ETB packet, the host 510 transmits an ACK packet and switches to the sender mode. In response to receiving the ACK packet from the host 510, the debugging component 122 switches to the receiver mode 550 from being in the sender mode. Then, the debugging component 122 begins periodically sending the C symbol packet indicating to the host 510 that the debugging component 122 is ready to receive packets from the host 510.

In view of the disclosure above, various examples are set forth below. It should be noted that one or more features of an example, taken in isolation or combination, should be considered within the disclosure of this application.
Example 1: A system comprising: a memory sub-system; a debugging component that is in a locked state by default; and a processing device, operatively coupled to the set of memory components and the debugging component, and configured to perform operations comprising: receiving, from a host over a first bus, authentication information associated with unlocking the debugging component; and in response to successfully authenticating the host based on the authentication information, unlocking the debugging component, the debugging component performing operations comprising: receiving one or more debug commands from the host via a second bus; and transmitting, to the host via the second bus, debugging information in response to receiving the one or more debug commands.
Example 2. The system of Example 1, wherein the debugging information includes a state of the memory sub-system representing a status of at least one of one or more data structures, one or more queues, or one or more state machines.
Example 3. The system of any one of Examples 1-2, wherein the debugging component performs operations comprising: receiving additional authentication information from the host via the second bus; and processing the one or more debug commands in response to successfully authenticating the host based on the additional authentication information.
Example 4. The system of Example 3, wherein the additional authentication information comprises a single use password (SUP).
Example 5. The system of any one of Examples 1-4, wherein the first bus comprises a system management bus (SMBus) and the second bus comprises a peripheral component interconnect express (PCIe) bus.
Example 6. The system of any one of Examples 1-5, wherein the debugging component comprises a universal asynchronous receiver-transmitter (UART) device.
Example 7. The system of any one of Examples 1-6, wherein the authentication information comprises a 256-bit key, and wherein the processing device successfully authenticates the host by comparing the authentication information with a known value.
Example 8. The system of any one of Examples 1-7, wherein the one or more debug commands comprise instructions to install debug firmware, the debugging component causing the processing device to boot using the debug firmware instead of default firmware, the debug firmware configured to generate different types of debugging information than the default firmware.
Example 9. The system of any one of Examples 1-8, wherein the memory sub-system is installed in an automotive environment and is associated with at least one of an infotainment system of the automotive environment or advanced driver assistance systems (ADAS) of the automotive environment.
Example 10. The system of any one of Examples 1-9, wherein the one or more debug commands are provided to the debugging component without physically detaching the memory sub-system from the host.
Example 11. The system of any one of Examples 1-10, wherein the debugging information comprises at least one of NVMe logs, Failure AnalysisDump/VendorSpecific logs, SMART logs, or SMART extended logs.
Example 12. The system of any one of Examples 1-11, wherein the one or more debug commands comprise at least one of a sanitize command to delete information stored in a set of memory components of the memory sub-system, a request to place the memory sub-system in a specific power state that prevents the memory sub-system from entering a low-power mode, a request to modify speed of the memory sub-system or clocking mode of the memory sub-system, or a request to restructure a namespace of the memory sub-system.
Example 13. The system of any one of Examples 1-12, wherein the authentication information is received in response to occurrence of a critical event of the memory sub-system.
Example 14. The system of Example 13, wherein the critical event comprises at least one of PCIe link drops, firmware asserts, command timeouts, entering of a write protect state in the memory sub-system, a loop of resets, and a threshold number of interrupts being transmitted by the processing device to the host.
Example 15. The system of any one of Examples 1-14, wherein the debugging component performs operations comprising: periodically sending a waiting-for-packet indicator; receiving one or more start-of-packet indicators from the host associated with respective one or more packets; sending an acknowledgment after receiving each of the one or more packets; receiving an end-of-transmission (EOT) indicator after the one or more packets are received; and receiving an end-of-transmission block (ETB) indicator to switch the debugging component from operating as a receiver to operating as a transmitter.
Example 16. The system of Example 15, wherein the one or more debug commands are received as part of the one or more packets, and wherein the debugging information is transmitted after the debugging component switches to operating as the transmitter.
Example 17. The system of any one of Examples 15-16, wherein the debugging component performs operations comprising: detecting an additional waiting-for-packet indicator received from the host; in response to detecting the additional waiting-for-packet indicator, transmitting a start-of-packet indicator associated with a debugging packet to the host; sending the EOT indicator after the debugging packet is transmitted; and transmitting the ETB indicator to switch the host from operating as the receiver to operating as the transmitter.
Example 18. The system of any one of Examples 1-17, wherein the debugging component returns to the locked state in response to receiving a lock command in the One or More Debug Commands

Methods and computer-readable storage medium with instructions for performing any one of the above Examples.

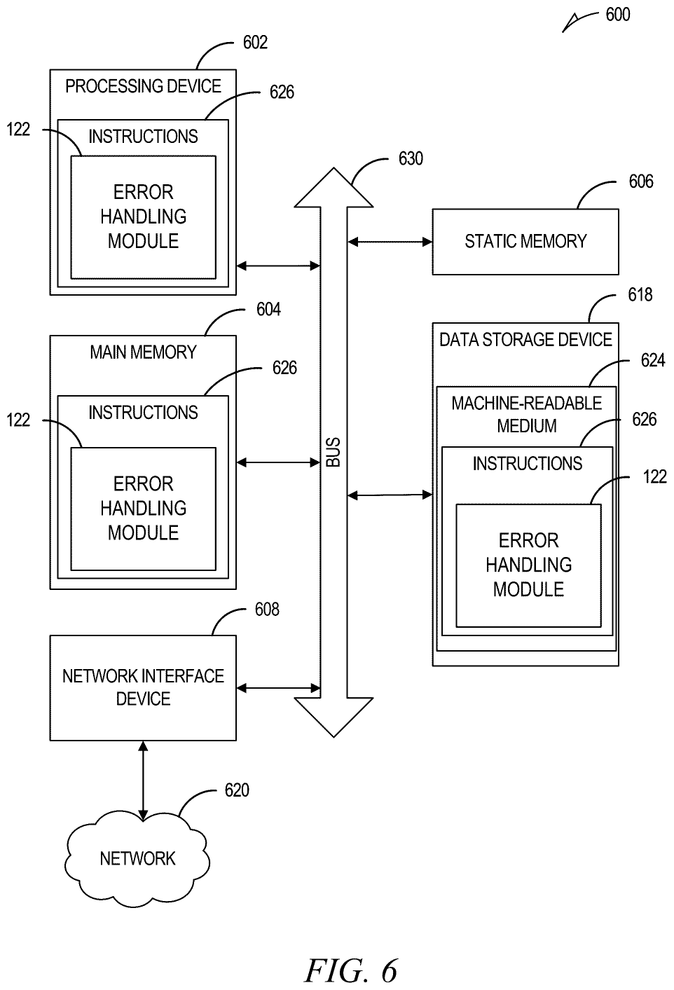

FIG. 6 illustrates an example machine in the form of a computer system 600 within which a set of instructions can be executed for causing the machine to perform any one or more of the methodologies discussed herein. In some examples, the computer system 600 can correspond to a host system (e.g., the host system 120 of FIG. 1) that includes, is coupled to, or utilizes a memory sub-system (e.g., the memory sub-system 110 of FIG. 1) or can be used to perform the operations of a controller (e.g., to execute an operating system to perform operations corresponding to the debugging component 122 of FIG. 1). In alternative examples, the machine can be connected (e.g., networked) to other machines in a local area network (LAN), an intranet, an extranet, and/or the Internet. The machine can operate in the capacity of a server or a client machine in a client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a network switch, a network bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 600 includes a processing device 602, a main memory 604 (e.g., read-only memory (ROM), flash memory, dynamic random access memory (DRAM) such as synchronous DRAM (SDRAM) or Rambus DRAM (RDRAM), etc.), a static memory 606 (e.g., flash memory, static random access memory (SRAM), etc.), and a data storage system 618, which communicate with each other via a bus 630.

The processing device 602 represents one or more general-purpose processing devices such as a microprocessor, a central processing unit, or the like. More particularly, the processing device 602 can be a complex instruction set computing (CISC) microprocessor, a reduced instruction set computing (RISC) microprocessor, a very long instruction word (VLIW) microprocessor, a processor implementing other instruction sets, or processors implementing a combination of instruction sets. The processing device 602 can also be one or more special-purpose processing devices such as an application specific integrated circuit (ASIC), a field programmable gate array (FPGA), a digital signal processor (DSP), a network processor, or the like. The processing device 602 is configured to execute instructions 626 for performing the operations and steps discussed herein. The computer system 600 can further include a network interface device 608 to communicate over a network 620.

The data storage system 618 can include a machine-readable storage medium 624 (also known as a computer-readable medium) on which is stored one or more sets of instructions 626 or software embodying any one or more of the methodologies or functions described herein. The instructions 626 can also reside, completely or at least partially, within the main memory 604 and/or within the processing device 602 during execution thereof by the computer system 600, the main memory 604 and the processing device 602 also constituting machine-readable storage media. The machine-readable storage medium 624, data storage system 618, and/or main memory 604 can correspond to the memory sub-system 110 of FIG. 1.

In one example, the instructions 626 include instructions to implement functionality corresponding to firmware slot manager (e.g., the debugging component 122 of FIG. 1). While the machine-readable storage medium 624 is shown in an example to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system's memories or registers or other such information storage systems.

The present disclosure also relates to an apparatus for performing the operations herein. This apparatus can be specially constructed for the intended purposes, or it can include a general-purpose computer selectively activated or reconfigured by a computer program stored in the computer. Such a computer program can be stored in a computer-readable storage medium, such as, but not limited to, any type of disk including floppy disks, optical disks, CD-ROMs, and magnetic-optical disks; read-only memories (ROMs); random access memories (RAMs); erasable programmable read-only memories (EPROMs); EEPROMs; magnetic or optical cards; or any type of media suitable for storing electronic instructions, each coupled to a computer system bus.

The algorithms and displays presented herein are not inherently related to any particular computer or other apparatus. Various general-purpose systems can be used with programs in accordance with the teachings herein, or it can prove convenient to construct a more specialized apparatus to perform the method. The structure for a variety of these systems will appear as set forth in the description above. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some examples, a machine-readable (e.g., computer-readable) medium includes a machine-readable (e.g., computer-readable) storage medium such as a read-only memory (ROM), random access memory (RAM), magnetic disk storage media, optical storage media, flash memory components, and so forth.

In the foregoing specification, examples of the disclosure have been described with reference to specific examples thereof. It will be evident that various modifications can be made thereto without departing from the examples of the disclosure as set forth in the following claims. The specification and drawings are, accordingly, to be regarded in an illustrative sense rather than a restrictive sense.

What is claimed is:

1. A system comprising:
a memory sub-system comprising a set of memory components;
a debugging component that is in a locked state by default; and
a processing device, operatively coupled to the set of memory components and the debugging component, and configured to perform operations comprising:
receiving, from a host over a first bus, authentication information associated with unlocking the debugging component; and
in response to successfully authenticating the host based on the authentication information, unlocking the debugging component, the debugging component performing operations comprising:
receiving one or more debug commands from the host via a second bus; and
transmitting, to the host via the second bus, debugging information in response to receiving the one or more debug commands.

2. The system of claim 1, wherein the debugging information includes a state of the memory sub-system representing a status of at least one of one or more data structures, one or more queues, or one or more state machines.

3. The system of claim 1, wherein the debugging component performs operations comprising:
receiving additional authentication information from the host via the second bus; and
processing the one or more debug commands in response to successfully authenticating the host based on the additional authentication information.

4. The system of claim 3, wherein the additional authentication information comprises a single use password (SUP).

5. The system of claim 1, wherein the first bus comprises a system management bus (SMBus) and the second bus comprises a peripheral component interconnect express (PCIe) bus.

6. The system of claim 1, wherein the debugging component comprises a universal asynchronous receiver-transmitter (UART) device.

7. The system of claim 1, wherein the authentication information comprises a 256-bit key, and wherein the processing device successfully authenticates the host by comparing the authentication information with a known value.

8. The system of claim 1, wherein the one or more debug commands comprise instructions to install debug firmware, the debugging component causing the processing device to boot using the debug firmware instead of default firmware, the debug firmware configured to generate different types of debugging information than the default firmware.

9. The system of claim 1, wherein the memory sub-system is installed in an automotive environment and is associated with at least one of an infotainment system of the automotive environment or advanced driver assistance systems (ADAS) of the automotive environment.

10. The system of claim 1, wherein the one or more debug commands are provided to the debugging component without physically detaching the memory sub-system from the host.

11. The system of claim 1, wherein the debugging information comprises at least one of NVMe logs, FailureAnalysisDump/VendorSpecific logs, SMART logs, or SMART extended logs.

12. The system of claim 1, wherein the one or more debug commands comprise at least one of a sanitize command to delete information stored in a set of memory components of the memory sub-system, a request to place the memory sub-system in a specific power state that prevents the memory sub-system from entering a low-power mode, a request to modify speed of the memory sub-system or clocking mode of the memory sub-system, or a request to restructure a namespace of the memory sub-system.

13. The system of claim 1, wherein the authentication information is received in response to occurrence of a critical event of the memory sub-system.

14. The system of claim 13, wherein the critical event comprises at least one of PCIe link drops, firmware asserts, command timeouts, entering of a write protect state in the memory sub-system, a loop of resets, and a threshold number of interrupts being transmitted by the processing device to the host.

15. The system of claim 1, wherein the debugging component performs operations comprising:
periodically sending a waiting-for-packet indicator;
receiving one or more start-of-packet indicators from the host associated with respective one or more packets;
sending an acknowledgment after receiving each of the one or more packets;
receiving an end-of-transmission (EOT) indicator after the one or more packets are received; and
receiving an end-of-transmission block (ETB) indicator to switch the debugging component from operating as a receiver to operating as a transmitter.

16. The system of claim 15, wherein the one or more debug commands are received as part of the one or more packets, and wherein the debugging information is transmitted after the debugging component switches to operating as the transmitter.

17. The system of claim 15, wherein the debugging component performs operations comprising:
detecting an additional waiting-for-packet indicator received from the host;
in response to detecting the additional waiting-for-packet indicator, transmitting a start-of-packet indicator associated with a debugging packet to the host;
sending the EOT indicator after the debugging packet is transmitted; and
transmitting the ETB indicator to switch the host from operating as the receiver to operating as the transmitter.

18. The system of claim 1, wherein the debugging component returns to the locked state in response to receiving a lock command in the one or more debug commands.

19. A method comprising:
receiving, by a processing device from a host over a first bus, authentication information associated with unlocking a debugging component;
in response to successfully authenticating the host based on the authentication information, unlocking a debugging component by the processing device;
receiving, by the debugging component, one or more debug commands from the host via a second bus; and
transmitting, by the debugging component to the host via the second bus, debugging information in response to receiving the one or more debug commands.

20. A non-transitory computer-readable storage medium comprising instructions that, when executed by a processing device, cause the processing device to perform operations comprising:
receiving, by a processing device from a host over a first bus, authentication information associated with unlocking a debugging component;
in response to successfully authenticating the host based on the authentication information, unlocking a debugging component by the processing device;
receiving, by the debugging component, one or more debug commands from the host via a second bus; and
transmitting, by the debugging component to the host via the second bus, debugging information in response to receiving the one or more debug commands.
